(19) United States
(12) Patent Application Publication
(10) Pub. No.: US 2007/0023914 A1
(43) Pub. Date: Feb. 1, 2007

(54) Electromigration resistant metallurgy device and method

(75) Inventor: Paul A. Farrar, Bluffton, SC (US)

Correspondence Address: SCHWEGMAN, LUNDBERG, WOESSNER & KLUTH, P.A., P.O. BOX 2938, MINNEAPOLIS, MN, 55402, US

(73) Assignee: Micron Technology, Inc.

(21) Appl. No.: 11/194,341

(22) Filed: Aug. 1, 2005

(51) Int. Cl. H01L 23/52

(52) U.S. Cl. 257/751

(57) ABSTRACT

Devices and methods are described including a conducting pathway with improved electromigration properties. The conducting pathway can be used in integrated circuits and semiconductor chips for devices such as semiconductor memory, or information handling systems. Conducting pathways are provided that eliminate electromigration problems without reducing conductivity in the conductive pathway. Embodiments using a carbon nanotube for the electromigration barrier segment provide the high electrical conductivity of carbon nanotubes, combined with a high resistance to atomic displacement from the nanotube microstructure.

### TECHNICAL FIELD

This disclosure relates to electrical conductors. Specifically this invention relates to interconnection structures on semiconductor chips.

### BACKGROUND

As semiconductor chip technology moves forward, chip designs are constantly getting smaller and demanding higher performance and faster operation. Semiconductor chips, such as memory chips, processor chips, etc. use transistors and other electrical devices to perform operations such as data storage and logic operations. The transistors and other electrical devices are interconnected to form a circuit, typically using conducting elements such as metal trace lines along a horizontal plane of a chip, and vias in a vertical direction.

As trace lines, vias and other conducting structures get smaller, a number of technical hurdles must be addressed. As current density in conductors increases, electromigration becomes more significant. Atoms from a conductor, such as a trace line, move under pressure from an electron wind, and the shifting of conductor atoms can cause unwanted conditions such as electrical shorts to other conductors, or open conditions where the conductors are no longer continuous.

### SUMMARY

The above mentioned problems such as electromigration in conductors are addressed and will be understood by reading and studying the following specification.

A conducting circuit pathway is shown that includes an insulator material substantially surrounding a conductor. The conductor includes a first conducting segment having a first length less than or equal to a first electromigration threshold length for a predetermined current density and a predetermined first conductor material. The conductor also includes a second conducting segment having a second length less than or equal to a second electromigration threshold length for the predetermined current density and a predetermined second conductor material. The conductor also includes an electrically conductive electromigration barrier segment coupled between the first conducting segment and the second conducting segment.

A conducting circuit system is also shown that includes a number of first conductive pathways having a first lateral direction across a semiconductor surface, and a number of second conductive pathways having a second lateral direction across the semiconductor surface. The conducting circuit system also includes an insulator material substantially surrounding the first and second conductive pathways. At least one pathway in the system includes a first conducting segment having a first length less than or equal to a first electromigration threshold length for a predetermined current density and a predetermined first conductor material. The pathway also includes a second conducting segment having a second length less than or equal to a second electromigration threshold length for the predetermined current density and a predetermined second conductor material. The pathway also includes an electrically conductive electromigration barrier segment coupled between the first conducting segment and the second conducting segment.

Devices such as memory devices and information handling systems can also be formed using conducting pathways as described in the present disclosure. These and other embodiments, aspects, advantages, and features will be set forth in part in the description which follows, and in part will become apparent to those skilled in the art by reference to the following description and referenced drawings. The scope of the invention should be determined with reference to the appended claims, along with the full scope of equivalents to which such claims are entitled.

### BRIEF DESCRIPTION OF THE DRAWINGS

FIG. 1 illustrates an information handling system according to an embodiment of the invention.

FIG. 2 illustrates a conducting pathway according to an embodiment of the invention.

FIG. 3 illustrates another conducting pathway according to an embodiment of the invention.

FIG. 4 illustrates a top view of a number of conductive pathways according to an embodiment of the invention.

FIG. 5 illustrates a side view of a number of conductive pathways according to an embodiment of the invention.

FIG. 6 illustrates a portion of a conductive pathway according to an embodiment of the invention.

FIG. 7 illustrates a method of forming a conductor according to an embodiment of the invention.

### DETAILED DESCRIPTION

In the following detailed description of the invention, reference is made to the accompanying drawings which form a part hereof, and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, electrical changes, etc. may be made without departing from the scope of the present invention.

The terms wafer and substrate used in the following description include any structure having an exposed surface with which to form the integrated circuit (IC) structure of the invention. The term substrate is understood to include semiconductor wafers. The term substrate is also used to refer to semiconductor structures during processing, and may include other layers, such as silicon-on-insulator (SOI), etc. that have been fabricated thereupon. Both wafer and substrate include doped and undoped semiconductors, epitaxial semiconductor layers supported by a base semiconductor or insulator, as well as other semiconductor structures well known to one skilled in the art. The term conductor is understood to include semiconductors, and the term insulator or dielectric is defined to include any material that is less electrically conductive than the materials referred to as conductors.

The term “horizontal” as used in this application is defined as a plane parallel to the conventional plane or surface of a wafer or substrate, regardless of the orientation of the wafer or substrate. The term “vertical” refers to a direction perpendicular to the horizontal as defined above. Prepositions, such as “on”, “side” (as in “sidewall”), “higher”, “lower”, “over” and “under” are defined with respect to the conventional plane or surface being on the top surface of the wafer or substrate, regardless of the orientation of the wafer or substrate.

The following detailed description is, therefore, not to be taken in a limiting sense, and the scope of the present invention is defined only by the appended claims, along with the full scope of equivalents to which such claims are entitled.

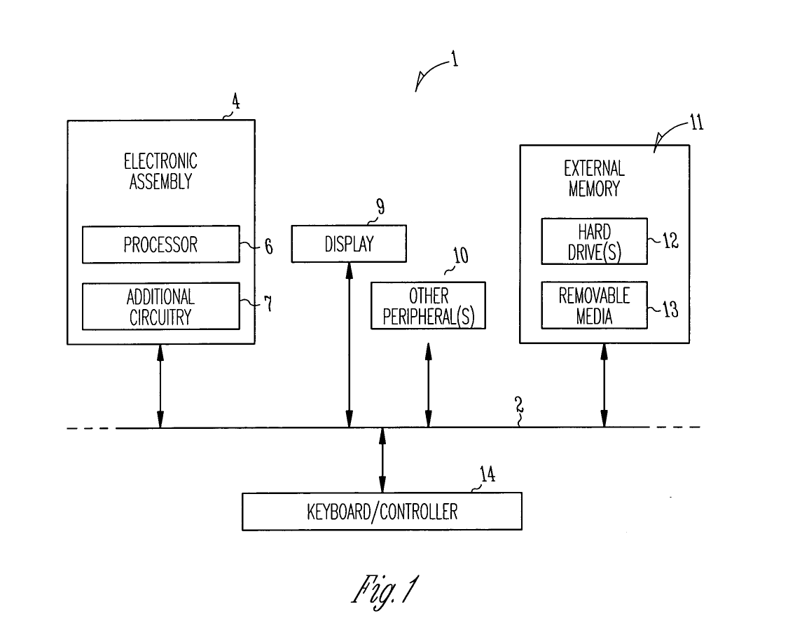

An example of an information handling system such as a personal computer is included to show an example of a high level device application for the present invention. FIG. 1 is a block diagram of an information handling system 1 incorporating at least one conducting pathway, such as a device interconnection trace, in accordance with one embodiment of the invention. Information handling system 1 is merely one example of an electronic system in which the present invention can be used. Other examples include, but are not limited to, personal data assistants (PDA's), cellular telephones, etc.

In this example, information handling system 1 comprises a data processing system that includes a system bus 2 to couple the various components of the system. System bus 2 provides communications links among the various components of the information handling system 1 and can be implemented as a single bus, as a combination of busses, or in any other suitable manner.

Electronic assembly 4 is coupled to the system bus 2. Electronic assembly 4 can include any circuit or combination of circuits. In one embodiment, electronic assembly 4 includes a processor 6 which can be of any type. As used herein, “processor” means any type of computational circuit, such as but not limited to a microprocessor, a microcontroller, a graphics processor, a digital signal processor (DSP), or any other type of processor or processing circuit.

In one embodiment, additional circuitry 7 is included on the electronic assembly 4. In one embodiment, the additional circuitry 7 includes logic circuitry. In one embodiment, the additional circuitry 7 includes local memory. Other circuits such as custom circuits, an application-specific integrated circuit (ASIC), etc. are also included in one embodiment of the invention.

Information handling system 1 can also include an external memory 11, which in turn can include one or more memory elements suitable to the particular application, such as one or more hard drives 12, and/or one or more drives that handle removable media 13 such as compact disks (CDs), digital video disks (DVDs), and the like.

Information handling system I can also include a display device 9 such as a monitor, additional peripheral components 10, such as speakers, etc. and a keyboard and/or controller 14, which can include game controllers, voice-recognition devices, or any other device that permits a system user to input information into and receive information from the information handling system 1.

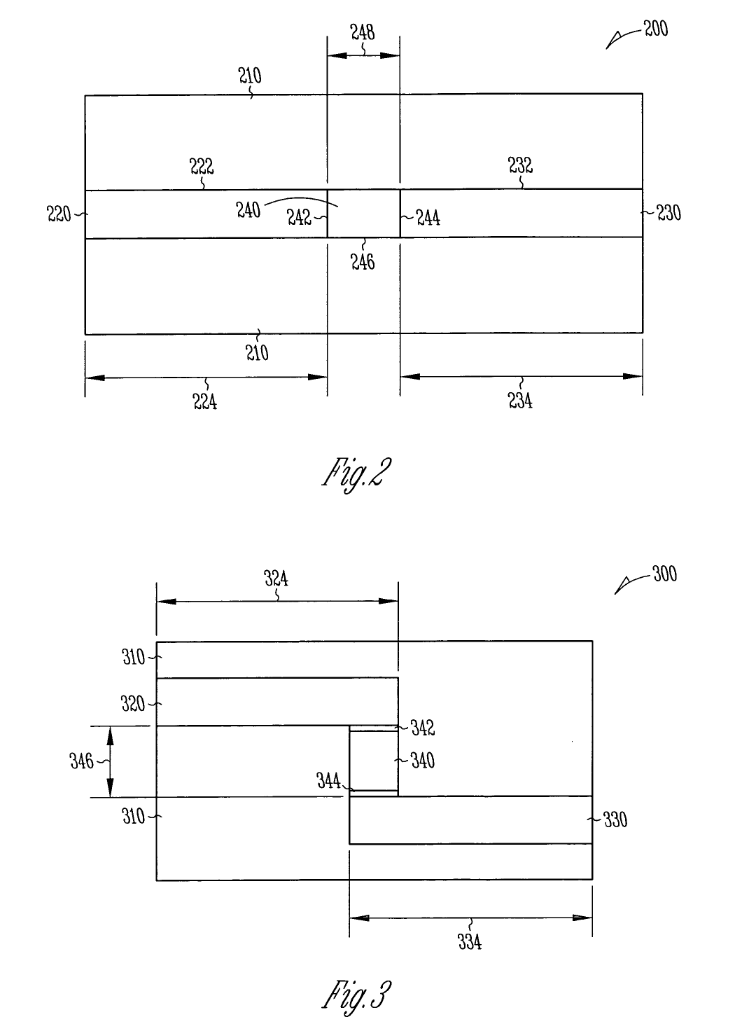

FIG. 2 shows a portion of a circuit 200 according to an embodiment of the invention. The circuit 200 includes a first conducting portion 220 and a second conducting portion 230. An electrically conductive electromigration barrier segment 240 is shown coupled between the first conducting portion 220 and the second conducting portion 230. In one embodiment, the first conducting portion 220, the second conducting portion 230, and the barrier segment 240 are contained within an insulator portion 210.

In one embodiment, the first conducting portion 220 and the second conducting portion 230 include metal trace elements. Although metal is used as an example of a conducting material for the first conducting portion 220 and the second conducting portion 230, other conducting materials such as semiconductors, conducting polymers, etc. are within the scope of the invention. In one embodiment, the insulator material includes an oxide material, such as a silicon dioxide. Other possible insulator materials include, but are not limited to, ceramic materials, polymers, etc. In one embodiment, a polymer insulator material includes a polyimide material.

As discussed in the background section above, one technical hurdle in integrated circuit design includes electromigration issues. Electromigration, or unwanted movement of atoms in a conductor, can lead to short circuits or open circuits, or other negative device performance issues. For a given device design, there exists a threshold conductor length, where a length longer than the threshold will exhibit electromigration, and a length below the threshold will not exhibit electromigration.

Some factors that influence the threshold length include, but are not limited to, conductor material choice, surrounding insulator material choice, stress state between the conductor and insulator, current density during device operation, etc. One of ordinary skill in the art, having the benefit of the present disclosure will recognize that a range of threshold lengths exist for any predetermined condition such as an aluminum trace line interconnect. One of ordinary skill in the art, having the benefit of the present disclosure will further recognize that a particular threshold length can be specified without undue experimentation once a particular device design is chosen (i.e. current density, insulator material choice, etc.).

In one embodiment, as shown in FIG. 2, the first conducting portion 220 includes a first length 224. In one embodiment, the second conducting portion 230 includes a second length 234. The first conducting portion 220 forms a first interface 222 with the insulator material 210, and the second conducting portion 230 forms a second interface 232 with the insulator material 210. In one embodiment the first length 224 includes a length that is less than or equal to an electromigration threshold length as determined by device parameters as described above. In one embodiment, a stress state at the first interface 222 between the insulator 210 and the first conductor 220 is a factor in determining the electromigration threshold length. Similar to the first length, in one embodiment the second length 234 includes a length that is less than or equal to an electromigration threshold length. In one embodiment, a stress state at the second interface 232 between the insulator 210 and the second conductor 230 is a factor in determining the electromigration threshold length as it relates to the second length 234.

As stated above, in one embodiment, the electromigration barrier segment 240 is coupled between the first conducting portion 220 and the second conducting portion 230. In one embodiment, the electromigration barrier segment 240 provides sufficient conduction for device operation, while concurrently providing a higher resistance to electromigration. In one embodiment, the electromigration barrier segment 240 includes a metal material that is different from the first or second conducting portions 220, 230.

In one embodiment, the electromigration barrier segment 240 includes a high melting temperature material such as a refractory metal. In one example, tungsten is included as the electromigration barrier segment 240. High melting temperature materials such as tungsten include advantages such as low diffusion rates which are useful in preventing electromigration.

In one embodiment, the electromigration barrier segment 240 includes an intermetallic compound. One example of an intermetallic compound includes an intermetallic of aluminum and copper. In one embodiment the aluminum copper compound includes Al₂Cu. Although an exact stoichiometry is shown, the actual ratios of aluminum to copper may vary in intermetallic embodiments. An advantage Al₂Cu includes high electrical conductivity, while concurrently exhibiting resistance to electromigration due to strong compound material bonds.

In one embodiment, the electromigration barrier segment 240 includes a carbon nanotube segment. In one embodiment, the electromigration barrier segment 240 includes a conductively doped portion of the insulator material 210, as will be discussed in more detail below.

In one embodiment, the electromigration barrier segment 240 includes a length 248. The electromigration barrier segment 240 forms an interface 242 with the first conducting portion 220 and an interface 244 with the second conducting portion 230. A further interface 246 is formed with the insulator material 210. Among other factors, stress conditions at these interfaces determine an electromigration threshold length for the electromigration barrier segment 240. In one embodiment, the length 248 of the electromigration barrier segment 240 is less than or equal to an electromigration threshold length for predetermined conditions of the electromigration barrier segment 240.

Conductive pathways 200 such as those illustrated in FIG. 2 include advantages such as eliminating electromigration problems without reducing conductivity in the conductive pathway. Embodiments using a carbon nanotube for the electromigration barrier segment 240 include advantages such as the high electrical conductivity of carbon nanotubes, combined with a high resistance to atomic displacement from the nanotube microstructure. Among other characteristics, resistance to atomic displacement, bond strength, etc. indicate a good barrier to electromigration between conducting portions.

FIG. 3 shows a conductive pathway 300 according to an embodiment of the invention. Similar to FIG. 2, a first conducting portion 320 is shown and a second conducting portion 330 is shown. The first and second conducting portions 320, 330 are included within an insulator material 310.

Similar to other embodiments shown, in one embodiment, the first conducting portion 320 includes a first length 324. In one embodiment, the second conducting portion 330 includes a second length 334. In one embodiment the first length 324 includes a length that is less than or equal to an electromigration threshold length as determined by device parameters. Similar to the first length, in one embodiment the second length 334 includes a length that is less than or equal to an electromigration threshold length. An electromigration barrier segment 340 is shown electrically coupled between the first conducting portion 320 and the second conducting portion 330. The electromigration barrier segment 340 as shown has a length 346. In one embodiment, the length 346 is less than or equal to an electromigration threshold length for predetermined material and environmental factors of the electromigration barrier segment 340.

As shown in FIG. 3, in one embodiment, the first conducting portion 320 is offset from the second conducting portion 330 so that they are not coaxial. The electromigration barrier segment 340 is shown in one embodiment as orthogonal between the first conducting portion 320 and the second conducting portion 330. In one embodiment, the first conducting portion 320 is located on a different plane from the second conducting portion 330. One example of two different planes includes two different fabrication levels in a semiconductor processing operation. In one embodiment, the electromigration barrier segment 340 serves as a via between fabrication levels.

In one embodiment, a first interface layer 344 is included between the electromigration barrier segment 340 and the second conducting portion 330. In one embodiment, the first interface layer 344 is included for improved material compatibility between the electromigration barrier segment 340 and the second conducting portion 330. Using a carbon nanotube as an example electromigration barrier segment 340, in one embodiment, the first interface layer 344 includes nickel. Nickel provides a suitable nucleation surface for the growth of carbon nanotubes, and is electrically conductive. Other interface layer materials include, but are not limited to, chromium, molybdenum, tantalum, tungsten, titanium, zirconium, hafnium, vanadium, aluminum, copper, silver, and gold. In one embodiment, a second interface layer 342 is also included between the electromigration barrier segment 340 and the first conducting portion 320.

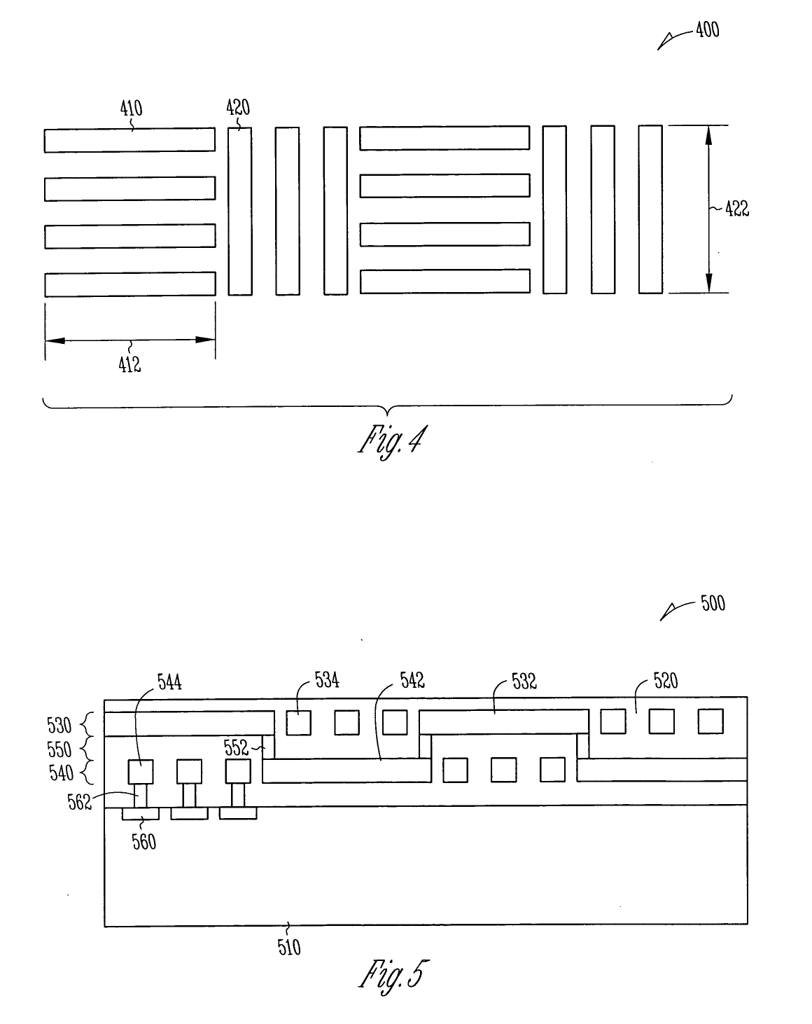

FIG. 4 shows a pattern of conductive portions 400 according to an embodiment of the invention. A first number of conductive portions 410 is shown with a first orientation, and a second number of conductive portions 420 is shown with a second orientation. In one embodiment, the first number of conductive portions 410 is oriented orthogonal to the second number of conductive portions 420.

The first number of conductive portions 410 is shown having a length 412. In one embodiment, the length 412 is less than or equal to an electromigration threshold length for the first number of conductive portions 410 as determined by device parameters. The second number of conductive portions 420 is shown having a length 422. In one embodiment, the length 422 is less than or equal to an electromigration threshold length for the second number of conductive portions 420 as determined by device parameters.

FIG. 5 shows a side view of a pattern of conductive portions 500 similar to the pattern 400 shown in FIG. 4. A substrate 510 is shown, with a number of electronic devices 560 included for illustration. Examples of electronic devices 560 include, but are not limited to, transistors, memory cells, capacitors, etc. In one embodiment, FIG. 5 illustrates a portion of a semiconductor memory device such as a dynamic random access memory, a flash memory, or other type of semiconductor integrated circuit. An insulator material 520 is shown to provide electrical isolation to devices, vias, and conducting pathways, etc. A number of device fabrication levels are shown over the substrate 510. A first level 530 is located away from the substrate 510, a second level 540 is located closer to the substrate, and an intermediate level 550 separates the first and second levels 530, 540.

A first number of conductive portions 532 and a second number of conductive portions 534 are located on the first level 530. As shown in FIG. 5, the first number of conductive portions 532 are substantially orthogonal to the second number of conductive portions 534, although the invention is not so limited. A third number of conductive portions 542 and a fourth number of conductive portions 544 are located on the second level 540. Similar to the first level 530, in one embodiment, the third number of conductive portions 542 are substantially orthogonal to the fourth number of conductive portions 544, although the invention is not so limited.

A number of electromigration barrier segments 552 are shown coupled between conductive portions on the first level 530 and the second level 540. Similar to embodiments described above, in one embodiment, the electromigration barrier segments 552 include a metal material that is different from the conductive portions. In one embodiment, the electromigration barrier segments 552 include carbon nanotube segments. In one embodiment, the electromigration barrier segments 552 include a conductively doped portion of the insulator material 520, as will be discussed in more detail below.

In one embodiment, the conductive portions are linked together using the electromigration barrier segments 552 to form conductive pathways through the insulator 520 and across a surface of the substrate 510. In one embodiment, a number of device contacts 562 are coupled between devices 560 and selected conductive portions, such as fourth number of conductive portions 544 as shown in FIG. 5.

One advantage of conductor pattern configurations as illustrated in FIG. 5, or other figures, includes a system that is capable of electrically connecting devices 560 on a surface of a semiconductor chip. Another advantage of a conductor pattern configuration as provided in FIG. 5 or selected embodiments above includes a system that substantially eliminates unwanted electromigration within interconnects. Features such as conductor portions that are formed below an electromigration threshold length provide high conductivity without negative side effects. In one embodiment, using electromigration barrier segments 552 such as carbon nanotubes, maintains or improves conductivity while removing electromigration issues. Features such as an alternating orthogonal design as shown in FIGS. 4 and 5 provide any number of possible interconnection pathways, depending on locations of electromigration barrier segments 552.

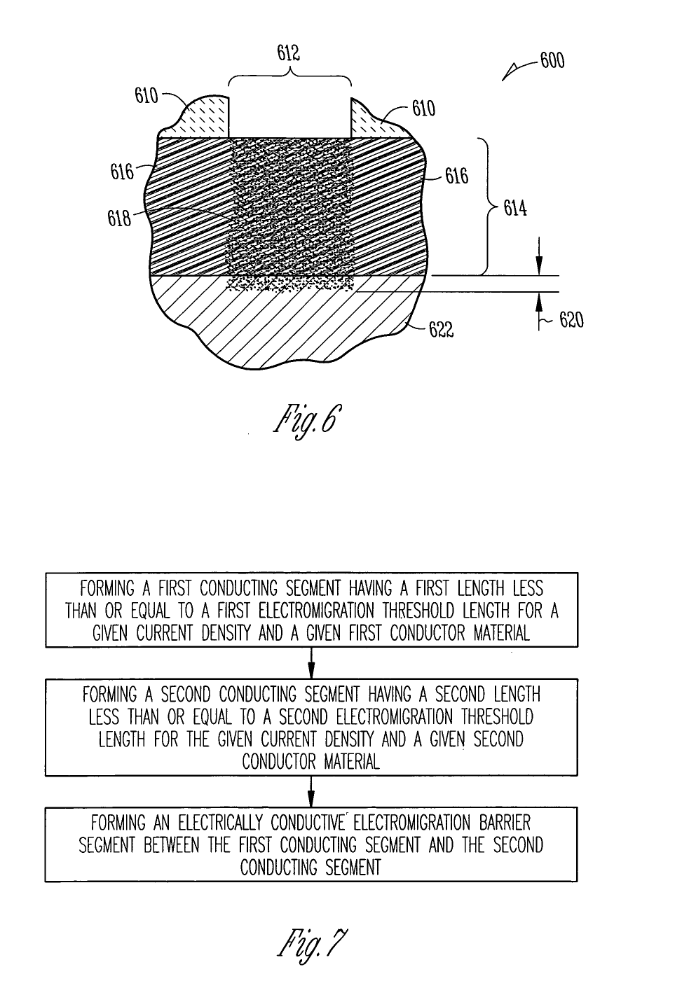

FIG. 6 shows an interconnection segment 618 according to an embodiment of the invention. In one embodiment interconnection segment 618 is used as an electromigration barrier segment between conductive segments as described in embodiments above. In one embodiment, the interconnection segment 618 is formed as shown in U.S. Pat. No. 6,017,829 to Paul Farrar, and assigned to Micron Technology, which is hereby incorporated by reference. FIG. 6 illustrates the result of ion-implantation into a material such as a polymer insulator material. In FIG. 6 an implanted interconnect 618 is illustrated wherein ions have been implanted within dielectric layer 616. A portion of implanted interconnect 618 overlaps into substrate 622. The overlap portion is an implanted overlap depth 620, that minimizes the electrical resistance interface and the thermal stress interface between interconnect 618 and adjacent electrically conductive regions. In one embodiment, implanted interconnect 618 will have a length in a range from about 1,000 Å to about 30,000 Å.

Formation of an active area simultaneously with formation of an interconnect makes the active area and the interconnect self-aligned. If substrate 622 is not doped, doping of substrate 622 can occur simultaneously with forming an interconnect in the region within and below etch hole 612 in upper layer 610. For example if substrate 622 is monocrystalline silicon, n-doping or p-doping can be performed by implanting selected ions. The ions that are implanted within substrate 622 will make that portion of substrate 622 into an electrically conductive region. For example, aluminum ions produce n-doping in a monocrystalline silicon substrate, and subsequent aluminum ion implantation, or another selected metal ion, will form implanted interconnect 614.

Although in one embodiment the substrate 622 is made of monocrystalline silicon, other substrates can be provided and doped simultaneously with formation of implanted interconnect 614. By way of example, semiconductors are fabricated from compounds made by a combination of elements from periodic table groups IA-VIIA, IIA-VIA, and IIIA-VA, as well as IA-IIA-VI₂A, and IIA-IVA-V₂.

In one embodiment, implanted overlap depth 620 expands laterally upon heat treatment to form, for example, an active area in a transistor source-drain structure.

Dielectric layer 616 can be selected to be an organometallic dielectric or equivalent that releases metal elements in favor of bonding with oxygens or nitrogens and equivalents. Treatment is carried out in an oxygen or nitrogen atmosphere following implantation. Implantation of metal ions to form implanted interconnect 614 or an implanted thermal conductor will, either spontaneously or with heat treatment, cause the metals in the organometallic dielectric to combine with the implanted metal ions to form a substantially coherent and continuous metal interconnect.

In one embodiment, combination of the metals in the organometallic and the implanted species accomplishes more metallization in the implanted interconnect 618 or in an implanted thermal conductor than simple implantation alone achieves. Combination also renders the organometallic dielectric that remains more resistant to electrical conductivity than regions not implanted with metal ions.

An alternative to an organometallic dielectric that releases its metal element in favor of oxides or nitrides, is an organometallic that releases its metal element by catalysis caused by the presence of the implanted metal species. By this optional method, the regions of dielectric not implanted by the metal ions do not become conductive at the temperatures at which the catalytic reaction occurs.

The following process is an example used to produce a no via-etch interconnect in a layer polyamide having a thickness of 10,000 Å. An appropriate mask is first put in place. This can be either a simple mask, a multiple-layer mask, or a stand-off mask covered by a thin metal or inorganic layer. The mask is then covered with an imaging resist layer. In any case, the mask must be thick enough to stop essentially all of the incoming implant species. The mask is then imaged to produce openings through which a series of implantations of the implant species are then performed.

If an electrical contact is desired, the energy of the implantation is chosen so that penetration of the implant species is substantially continuous through the dielectric layer to the substrate. The energy of the implantation and the range of the depth of penetration of each implanted level can be calculated using, for example, a Monte Carlo simulation of the scatter and subsequent distribution of each of the required implant levels.

Calculations are given below in Table 1 for the formation of an implanted conductor in a dielectric layer having a thickness of about 10,000 Å and being substantially composed of BPDA-ODA or PMDA-ODA. The implanted conductor is formed by applying a first mask as a 5000 Å thick positive photo resist. A second mask is applied as a 5,000 Å thick Si₃N₄ layer. A third mask is applied as a 2000 Å top imaging photo resist. The masks are exposed and patterned to form a mask that will facilitate ion implantation to form an implanted interconnect. Implantation of nickel is then carried out. The remaining portions of the masks serve to mask out unwanted ion implantation. Table 1 illustrates eight (8) implantation steps of this example embodiment.

TABLE 1

| Implant # | Implant Energy | | Implant dose |
|---|---|---|---|
| 1 | 825 | KEV | 1.35 10¹⁸ |
| 2 | 410 | KEV | 8.98 10¹⁷ |
| 3 | 175 | KEV | 3.2 10¹⁷ |
| 4 | 70 | KEV | 1.3 10¹⁷ |
| 5 | 20 | KEV | 7.0 10¹⁶ |
| 6 | 5 | KEV | 1.6 10¹⁶ |
| 7 | 900 | V | 1.3 10¹⁶ |
| 8 | 80 | V | 4.0 10¹⁶ |

Illustration of the method of the present example continues by removing all masks and metallizing the structure with appropriate electrically conductive materials. Following connection of implanted interconnects to metallization lines, additional layers may then be built upon the present structure, such as by depositing a second dielectric layer and continuing to build up the device.

Implant dose and energy are a function of the qualities of both the dielectric layer and the implanted species. Variation of the type of material of the dielectric layer and the implanted species to achieve a desired structure are contemplated. Table 2 illustrates the result of a nickel implant in the inventive example.

TABLE 2

| Distance from Upper Surface | |
|---|---|
| of Dielectric Layer (Å) | Ni, Percent |
| 0-20 | 42 |
| 20-50 | 73 |
| 50-100 | 37 |
| 100-150 | 42 |
| 150-200 | 46 |
| 200-300 | 72 |
| 300-400 | 45 |
| 400-600 | 33 |
| 600-800 | 51 |
| 800-1000 | 47 |
| 1000-1250 | 33 |
| 1250-1500 | 44 |
| 1500-1750 | 53 |
| 1750-2000 | 56 |
| 2000-2500 | 43 |
| 2500-3000 | 33 |
| 3000-3500 | 38 |
| 3500-4000 | 86 |
| 4000-4500 | 95 |
| 4500-5000 | 66 |
| 5000-5500 | 36 |
| 5500-6000 | 41 |
| 6000-6500 | 31 |
| 6500-7000 | 40 |
| 7000-7500 | 48 |
| 7500-8000 | 67 |
| 8000-8500 | 86 |
| 8500-9000 | 68 |
| 9000-9500 | 49 |
| 9500-10000 | 66 |

As can be seen in Table 2, the minimum nickel concentration in any segment of 500 Å or less is at least 31 percent. A preferred random distribution of metal atoms in a range from about 35 percent to about 40 percent metal provides enough electrically conductive material to give sufficient contact, whereas more than about four percent and less than about 10 percent is preferably in a segregated mixture. Depending upon the nature of the implant, some segregation will occur.

It may be desirable to anneal an implanted conductive structure to distribute the implanted species. Anneal conditions are chosen so that diffusion takes place in the implanted columns but no significant atom diffusion occurs between adjacent implanted areas. As implant damage occurs in areas of implantation, local diffusion rates in these areas will be enhanced.

In cases where an implanted conductive structure segregates during anneal into grain or sub-grain boundaries of the dielectric layer, a reduced amount of implant is required to give adequate electrical interconnect qualities. When the dielectric layer is a polymer, as in the above-given example, an example heat treatment is in a range from about 300 to about 500 degrees centigrade. In one embodiment the temperature is about 400 degrees centigrade. In the case of the above-given example, curing of the polyamide dielectric layer provides required heat for annealing of the implanted conductive structure.

Heat treatment following implantation can be beneficial. For instance, an implanted conductive structure within a dielectric layer that overlaps into a semiconductor substrate will expand laterally upon heat treatment to form, for, example, an active area associated with a transistor source-drain structure.

FIG. 7 illustrates a method of formation of a conductor substantially within an insulator material. In one embodiment, the method includes forming a first conducting segment having a first length less than or equal to a first electromigration threshold length for a predetermined current density and a predetermined first conductor material. Another operation includes forming a second conducting segment having a second length less than or equal to a second electromigration threshold length for the predetermined current density and a predetermined second conductor material. Another operation includes forming an electrically conductive electromigration barrier segment between the first conducting segment and the second conducting segment.

### Conclusion

Using devices and methods as described above, a conducting pathway is provided with improved electromigration properties. The conducting pathway can be used in integrated circuits and semiconductor chips for devices such as semiconductor memory, or information handling systems. One advantage of conducting pathway designs as shown above includes eliminating electromigration problems without reducing conductivity in the conductive pathway. Embodiments using a carbon nanotube for the electromigration barrier segment include advantages such as the high electrical conductivity of carbon nanotubes, combined with a high resistance to atomic displacement from the nanotube microstructure. Other advantages include a system that is capable of electrically connecting devices on a surface of a semiconductor chip. Features such as conductor portions that are formed below an electromigration threshold length provide high conductivity without negative side effects. In one embodiment, using electromigration barrier segments, such as carbon nanotubes, maintains or improves conductivity while removing electromigration issues. Features such as an alternating orthogonal design provide any number of possible interconnection pathways, depending on locations of electromigration barrier segments.

Although selected advantages are detailed above, the list is not intended to be exhaustive. Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the present invention. It is to be understood that the above description is intended to be illustrative, and not restrictive. Combinations of the above embodiments, and other embodiments will be apparent to those of skill in the art upon reviewing the above description. The scope of the invention includes any other applications in which the above structures and fabrication methods are used. The scope of the invention should be determined with reference to the appended claims, along with the full scope of equivalents to which such claims are entitled.

What is claimed is:

1. A conducting circuit pathway, comprising:
an insulator material substantially surrounding a conductor, wherein the conductor includes:
a first conducting segment having a first length less than or equal to a first electromigration threshold length for a predetermined current density and a predetermined first conductor material;
a second conducting segment having a second length less than or equal to a second electromigration threshold length for the predetermined current density and a predetermined second conductor material; and
an electrically conductive electromigration barrier segment coupled between the first conducting segment and the second conducting segment.

2. The conducting circuit pathway of claim 1, wherein the first conducting segment is located within a first layer on a semiconductor chip, and the second conducting segment is located within a second layer parallel to the first layer.

3. The conducting circuit pathway of claim 1, wherein the electromigration barrier segment includes a metal different from the first conducting segment and the second conducting segment.

4. The conducting circuit pathway of claim 2, wherein the electromigration barrier segment includes a via between the first layer and the second layer.

5. The conducting circuit pathway of claim 4, wherein the via includes tungsten.

6. The conducting circuit pathway of claim 4, wherein the via is filled with a conducting metal compound.

7. The conducting circuit pathway of claim 6, wherein the conductive metal compound includes Al₂Cu.

8. The conducting circuit pathway of claim 4, wherein the via includes a carbon nanotube.

9. The conducting circuit pathway of claim 5, further including a nickel intermediate layer between the carbon nanotube and the first conducting segment.

10. The conducting circuit pathway of claim 4, wherein the insulator includes a polymer insulator.

11. The conducting circuit pathway of claim 10, wherein the via includes a conductively implanted region within the polymer insulator.

12. A conducting circuit system, comprising:
a number of first conductive pathways having a first lateral direction across a semiconductor surface;
a number of second conductive pathways having a second lateral direction across the semiconductor surface;
an insulator material substantially surrounding the first and second conductive pathways, wherein at least one pathway in the system includes:
a first conducting segment having a first length less than or equal to a first electromigration threshold length for a predetermined current density and a predetermined first conductor material;
a second conducting segment having a second length less than or equal to a second electromigration threshold length for the predetermined current density and a predetermined second conductor material; and
an electrically conductive electromigration barrier segment coupled between the first conducting segment and the second conducting segment.

13. The conducting circuit system of claim 12, wherein the first direction is substantially orthogonal to the second direction.

14. The conducting circuit system of claim 12, wherein the number of first conductive pathways and the number of second conductive pathways are interlaced.

15. The conducting circuit system of claim 12, wherein the first conducting segment and the second conducting segment are formed from the same material and are the same length.

16. The conducting circuit system of claim 12, wherein the electromigration barrier segment includes a carbon nanotube.

17. The conducting circuit system of claim 16, further including an intermediate layer between the carbon nanotube and at least one conductive segment.

18. A memory device, comprising:
a number of memory cells located on a semiconductor chip;
at least one conductor connecting one or more of the memory cells;
an insulator material substantially surrounding the conductor, wherein the conductor includes:
a first conducting segment having a first length less than or equal to a first electromigration threshold length for a predetermined current density and a predetermined first conductor material;
a second conducting segment having a second length less than or equal to a second electromigration threshold length for the predetermined current density and a predetermined second conductor material; and
an electrically conductive electromigration barrier segment coupled between the first conducting segment and the second conducting segment.

19. The memory device of claim 18, wherein the memory cells include dynamic random access memory cells.

20. The memory device of claim 18, wherein the insulator includes polyimide.

21. The memory device of claim 18, wherein the insulator includes a ceramic.

22. The memory device of claim 18, wherein the electromigration barrier segment includes a carbon nanotube.

23. An electronic device, comprising:
a processor;
a memory device coupled to the processor, wherein the memory device includes:
a number of memory cells located on a semiconductor chip;
at least one conductor connecting one or more of the memory cells;
an insulator material substantially surrounding the conductor, wherein the conductor includes:
a first conducting segment having a first length less than or equal to a first electromigration threshold length for a predetermined current density and a predetermined first conductor material;
a second conducting segment having a second length less than or equal to a second electromigration threshold length for the predetermined current density and a predetermined second conductor material; and
an electrically conductive electromigration barrier segment coupled between the first conducting segment and the second conducting segment.

24. The electronic device of claim 23, wherein the memory device includes a flash memory device.

25. The electronic device of claim 23, wherein the electromigration barrier segment includes a carbon nanotube.

26. The electronic device of claim 23, wherein the insulator includes polyimide and the electromigration barrier segment includes a conductively implanted region within the polyimide insulator.

27. A conducting circuit pathway, comprising:
an insulator material substantially surrounding a conductor, wherein the conductor includes:
a first conducting segment having a first length less than or equal to a first electromigration threshold length for a predetermined current density and a predetermined first conductor material;
a second conducting segment having a second length less than or equal to a second electromigration threshold length for the predetermined current density and a predetermined second conductor material; and
a means for preventing electromigration coupled between the first conducting segment and the second conducting segment.

28. The conducting circuit pathway of claim 27, wherein the means for preventing electromigration includes a carbon nanotube.

29. The conducting circuit pathway of claim 28, further including an intermediate layer between the first conductive segment and the carbon nanotube, the intermediate layer being chosen from a group consisting of nickel, chromium, molybdenum, tantalum, tungsten, titanium, zirconium, hafnium, vanadium, aluminum, copper, silver, and gold.

30. The conducting circuit pathway of claim 27, wherein the insulator material includes polyimide, and the means for preventing electromigration includes an implanted conductor segment.

31. A method, comprising:
forming a conductor substantially within an insulator material, wherein forming the conductor includes:
forming a first conducting segment having a first length less than or equal to a first electromigration threshold length for a predetermined current density and a predetermined first conductor material;
forming a second conducting segment having a second length less than or equal to a second electromigration threshold length for the predetermined current density and a predetermined second conductor material; and
forming an electrically conductive electromigration barrier segment between the first conducting segment and the second conducting segment.

32. The method of claim 31, wherein forming the electrically conductive electromigration barrier segment includes forming a carbon nanotube segment.

33. The method of claim 32, wherein forming the carbon nanotube segment includes growing a carbon nanotube on an intermediate material located over a portion of the first conducting segment.

34. The method of claim 33, wherein growing the carbon nanotube on the intermediate material includes growing the carbon nanotube on a nickel layer.

35. The method of claim 31, wherein forming the conductor substantially within the insulator material includes forming a conductor substantially within polyimide, and wherein forming an electrically conductive electromigration barrier segment includes implanting conductive particles into the polyimide.
